(19) United States
(12) Patent Application Publication
(10) Pub. No.: US 2008/0093981 A1
(43) Pub. Date: Apr. 24, 2008

(54) Electron Injecting Composition, and Light Emitting Element and Light Emitting Device Using the Electron Injecting Composition

(75) Inventors: Yasuo Nakamura, Tokyo (JP); Ryoji Nomura, Kanagawa (JP)

Correspondence Address: ERIC ROBINSON, PMB 955, 21010 SOUTHBANK ST., POTOMAC FALLS, VA, 20165, US

(73) Assignee: SEMICONDUCTOR ENERGY LABORATORY CO., LTD., Atsugi-shi (JP)

(21) Appl. No.: 11/660,755

(22) PCT Filed: Aug. 12, 2005
(86) PCT No.: PCT/JP05/15110

§ 371 Date: Feb. 22, 2007

(30) Foreign Application Priority Data
Aug. 23, 2004 (JP) 2004-242984

(51) Int. Cl. H01L 27/28; C09K 11/06

(52) U.S. Cl. 313/504; 252/301.16

(57) ABSTRACT

It is an object of the present invention to provide an electron injecting composition which is excellent in light-transmitting property, safety and electron injecting property, and a light emitting element and a light emitting device using the electron injecting composition. The electron injecting composition according to the present invention includes a benzoxazole derivative indicated by a general formula (1) and an electron donating organic compound; (where Ar is an aryl group, each of R1 to R4 represents hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group).

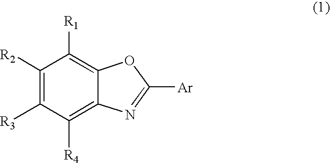

### TECHNICAL FIELD

The present invention relates to a light-emitting element including a pair of electrodes and a layer containing an organic compound, from which luminescence is obtained by applying an electric field, and more particularly, relates to an electron injecting composition, a light-emitting element formed by using the electron injecting composition, and a light-emitting device including the light-emitting element.

### BACKGROUND ART

A light-emitting element using a luminescent material has features of thinness and lightweight, high response speed, low direct-current voltage drive and the like, and is expected to be applied to a next-generation flat panel display. A light-emitting device in which light-emitting elements are arranged in a matrix has superiority in wide viewing angle and high visibility as compared with conventional liquid crystal display devices.

The light emission mechanism of a light-emitting element is said to be as follows: An electron injected from a cathode and a hole injected from an anode are recombined in the luminescence center in a light emitting layer to form a molecular exciton by applying a voltage to a pair of electrodes with the light emitting layer interposed therebetween, and energy is released to emit light when the molecular exciton returns to the ground state. An excited singlet state and an excited triplet state are known as an excited state, and it is believed that light can be emitted through either state.

As for such a light emitting element, improvement of an element structure, a development of a material and the like have been conducted in order to improve element characteristics.

FIG. 8 shows a general structure of a light emitting element. In FIG. 8, a layer 1002 containing a luminescent material is formed between an anode 1001 and a cathode 1003. When light that is generated in the layer 1002 containing the luminescent material is extracted from the anode side, the anode is formed of a light-transmitting material. On the other hand, when light is taken out from the cathode side, the cathode is formed of a light-transmitting material. Further, when light is taken out from both sides, it is necessary that the anode and the cathode be formed of a light-transmitting material.

However, indium tin oxide (hereinafter referred to as ITO) or the like that is used as a light-transmitting conductive film mostly has a higher work function. Therefore, when the material is used as a cathode, an electron injecting barrier from a cathode to a layer containing a luminescent material is large, which causes a problem of increasing the drive voltage.

In order to solve the problem, it has been proposed to provide a buffer layer (also referred to as an electron injecting metal layer or an electron injecting layer) between the layer containing the luminescent material and the cathode. For example, a structure is described in Patent Document 1, in which a very thin film of a metal that has a lower work function or an alloy of the metal is used as the buffer layer.

In Patent Document 1, an example of a magnesium-silver alloy is concretely described. However, the magnesium-silver alloy is a material that intrinsically absorbs visible light, and the light-transmitting property thereof is retained by making the magnesium-silver alloy into a very thin film. Therefore, the light-transmitting property is not so high, and the extraction efficiency of light that is generated in a layer containing a luminescent material is low.

In addition, as the buffer layer (an electron injecting layer), it has been also proposed to use copper phthalocyanine (hereinafter referred to as Cu-Pc), bathocuproin (2,9-dimethyl-4,7-diphenyl-1,10-phenanthroline: hereinafter referred to as BCP) or the like doped with an alkali metal (refer to Non Patent Document 1 and Non Patent Document 2).

However, there are problems that Cu-Pc absorbs visible light so that the light extraction efficiency is decreased, in addition, the glass-transition temperature of BCP is low so that BCP is easily crystallized, and the like.

Moreover, an alkali metal reacts actively. Thus, an alkali metal that adheres, in a thin film shape, to a protection sheet of an evaporation chamber and the like reacts with nitrogen to generate unstable nitride during vent (treatment by which the reduced pressure returns to the ambient pressure by air or nitrogen) or when the alkali metal contacts with atmospheric air. For example, when a metal such as lithium is evaporated, lithium nitride is generated after vent. However, there is a fear that lithium nitride can reacts with water and oxygen in atmospheric air and ignites as a result. Therefore, it is danger to use an alkali metal such as lithium in mass production since accidents such as a fire can occur.

[Patent Document 1]

Japanese Patent Application Laid-Open No.: Hei 8-185984

[Non Patent Document 1]

Junji Kido, Toshio Matsumoto, Applied Physics Letters, Vol. 73, No. 20 (16 Nov. 1998), 2866-2868

[Non Patent Document 2]

G. Parthasarathy, C. Adachi, P. E. Burrows, S. R. Forrest, Applied Physics Letters, Vol. 76, No. 15 (10 Apr. 2000), 2128-2130

### DISCLOSURE OF INVENTION

In view of the problems described above, it is an object of the present invention to provide an electron injecting composition which is excellent in light-transmitting property, safety and electron injecting property, and provide a light emitting element and a light emitting device using the electron injecting composition.

The present invention provides an electron injecting composition including a benzoxazole derivative indicated by a general formula (1) and an electron donating organic compound, and provides a light emitting element and a light emitting device using the electron injecting composition.

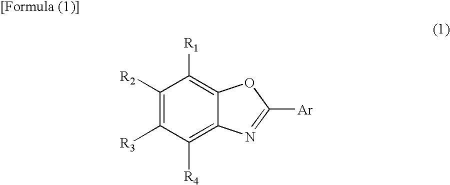

(where Ar is an aryl group, R1 to R4 are independently hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group)

Specific examples of the benzoxazole derivative indicated by the general formula (1) include 4,4′-Bis(5-methyl benzoxazol-2-yl)stilbene indicated by a structural formula (2), 2-(4-Biphenylyl)-6-phenylbenzoxazole indicated by a structural formula (3), 2,5-Bis(5′-tert-butyl-2′-benzoxazolyl)thiophene indicated by a structural formula (4), and the like.

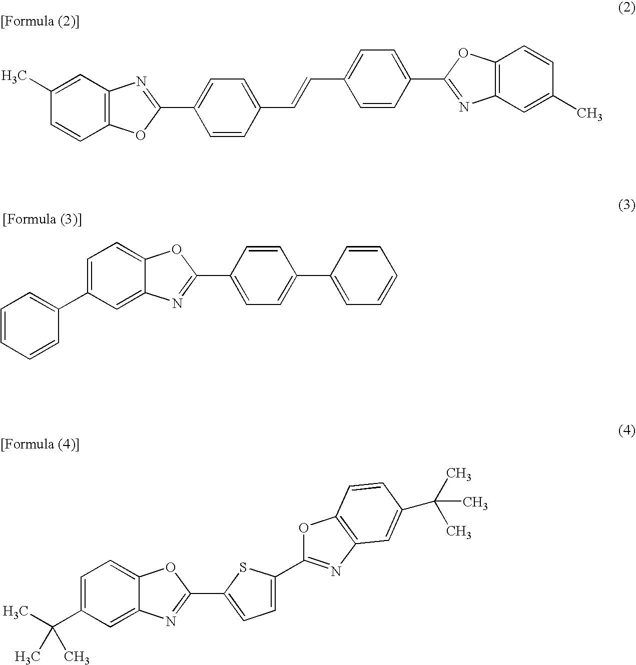

In the aspect described above, the electron donating organic compound can be a tetrathiafulvalene derivative indicated by a general formula (5).

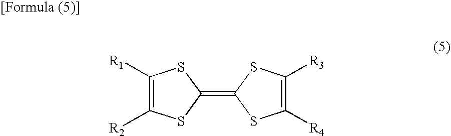

(where R1 to R4 are independently hydrogen, halogen, a cyano group, an alkyl group having 1 to 10 carbon atoms, a haloalkyl group having 1 to 10 carbon atoms, or an alkoxyl group having 1 to 10 carbon atoms, a substituted or unsubstituted aryl group, or a substituted or unsubstituted heterocyclic group)

Specific examples of the tetrathiafulvalene derivative indicated by the general formula (5) include (2,2′-bi(1,3-dithiol-2-ylidene: hereinafter referred to as TTF) indicated by a structural formula (6), Bis(ethylenedithio)tetrathiafluvalene indicated by a structural formula (7), Bis(ethylenedioxo)tetrathiafluvalene indicated by a structural formula (8), and the like.

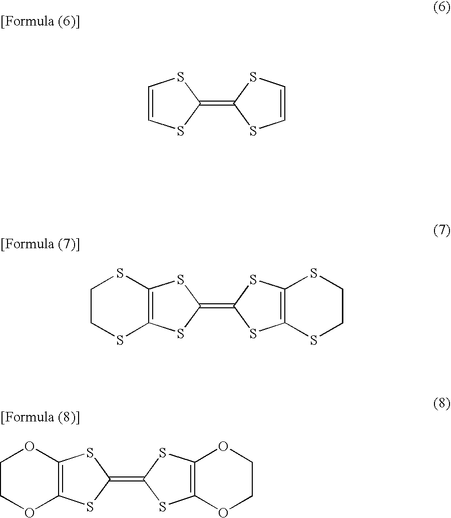

A light emitting element according to the present invention includes an anode, a cathode, and a layer containing a luminescent material between the anode and the cathode, and has a feature that a layer containing a benzoxazole derivative indicated by a general formula (1) and an electron donating organic compound is provided in contact with the cathode as a portion of the layer containing the luminescent material.

A light emitting element according to the present invention has a feature that a molar ratio of a benzoxazole derivative indicated by a general formula (1) or a structural formula (2) to (5) to an electron donating organic compound is from 0.5 to 10.

A light emitting device according to the present invention includes a light emitting element including an anode, a cathode, and a layer containing a luminescent material between the anode and the cathode, and has a feature that a layer containing a benzoxazole derivative indicated by a general formula (1) and an electron donating organic compound is provided in contact with the cathode as a portion of the layer containing the luminescent material.

The electron injecting composition according to the present invention is excellent in light-transmitting property. Therefore, light from the luminescent material can be emitted outside efficiently, when a light emitting element is formed by using the electron injecting composition according to the present invention.

Further, only organic compounds are used to form the electron injecting composition according to the present invention. Therefore, the use of the electron injecting composition according to the present invention makes it possible to manufacture a light-emitting element and a light-emitting device safely.

Moreover, the electron injecting composition according to the present invention has excellent electron injecting property. Therefore, a light-emitting element that is driven at a lower voltage can be manufactured by forming a light-emitting element with the use of the electron injecting composition according to the present invention. In addition, a light-emitting device that needs less power consumption can be manufactured.

### BRIEF DESCRIPTION OF DRAWINGS

In the accompanying drawings:

FIG. 1 is a diagram illustrating a light emitting element according to the present invention.

FIG. 2 is a diagram illustrating a light emitting element according to the present invention.

FIG. 3 is a diagram illustrating a light emitting element according to the present invention.

FIG. 4 is a diagram illustrating a light emitting element according to the present invention.

FIGS. 5A and 5B are diagrams illustrating a light emitting device.

FIGS. 6A and 6B are diagrams illustrating a light emitting device.

FIGS. 7A to 7E are diagrams illustrating electronic devices.

FIG. 8 is a diagram illustrating a conventional light emitting element.

### BEST MODE FOR CARRYING OUT THE INVENTION

Hereinafter, embodiment modes of the present invention will be described in detail with reference to the accompanying drawings. However, the present invention is not limited to the following description, and various changes and modifications for the modes and details thereof will be apparent to those skilled in the art unless such changes and modifications depart from the spirit and scope of the invention. Therefore, the present invention should not be interpreted as being limited to what is described in the embodiment modes described below.

### Embodiment Mode 1

In the present embodiment mode, an electron injecting composition according to the present invention will be described.

An electron injecting composition according to the present invention includes a benzoxazole derivative indicated by the general formula (1) and an electron donating organic compound.

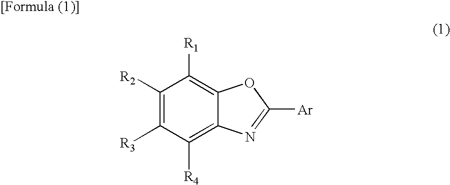

(where Ar is an aryl group, R1 to R4 are independently hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group)

In the electron injecting composition according to the present invention, a molar ratio of a benzoxazole derivative indicated by a general formula (1) or a structural formula (2) to (5) to an electron donating organic compound is from 0.5 to 10.

In the electron injecting composition according to the present invention, the benzoxazole derivative serves as an electron acceptor, and the electron donating organic compound serves as an electron donor. Therefore, the electron injecting composition according to the present invention has a high electron injecting property.

In addition, the benzoxazole derivative is excellent in light-transmitting property; and thus, the electron injecting composition according to the present invention also has a high light-transmitting property.

In addition, only organic compounds are used to form the electron injecting composition according to the present invention, and a highly-dangerous material such as an alkali metal is not used. Therefore, the electron injecting composition according to the present invention is excellent in safety.

Moreover, the electron injecting composition according to the present invention is not easily crystallized. Therefore, when the electron injecting composition according to the present invention is used to form a light emitting element, a light emitting element that has a longer lifetime can be formed.

Further, specific examples of the benzoxazole derivative indicated by the general formula (1) include 4,4′-Bis(5-methyl benzoxazol-2-yl)stilbene indicated by the structural formula (2), 2-(4-Biphenylyl)-6-phenylbenzoxazole indicated by the structural formula (3), 2,5-Bis(5′-tert-butyl-2′-benzoxazolyl)thiophene indicated by the structural formula (4), and the like.

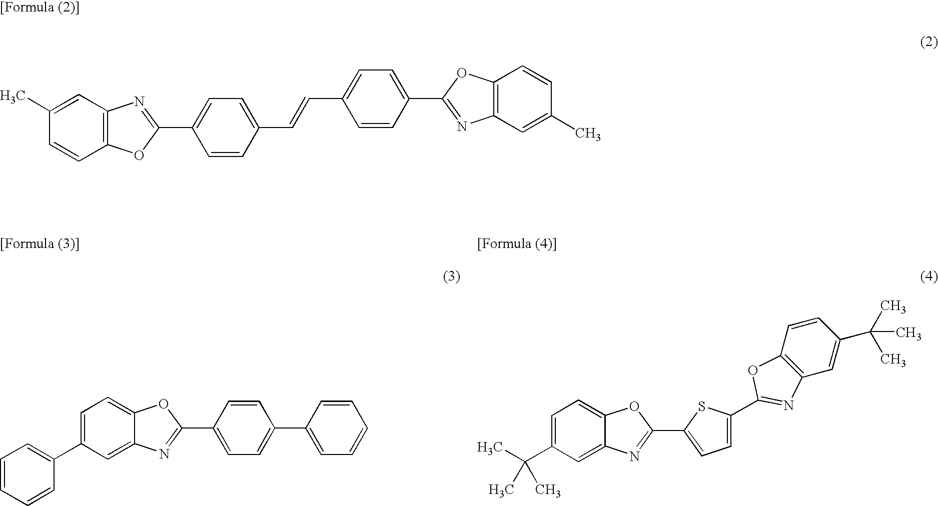

It is to be noted that the benzoxazole derivative that is used for the electron injecting composition according to the present invention is not limited to the materials indicated by the structural formulas (2) to (4).

Electron donating organic compounds that can be used for the electron injecting composition according to the present invention include a tetrathiafulvalene derivative indicated by the general formula (5).

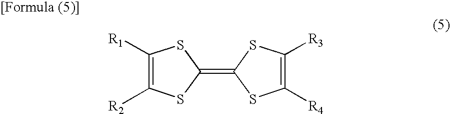

(where R1 to R4 are independently hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group)

In addition, specific examples of the tetrathiafulvalene derivative indicated by the general formula (5) include (2,2′-bi(1,3-dithiol-2-ylidene: hereinafter referred to as TTF) indicated by the structural formula (6), Bis(ethylenedithio)tetrathiafluvalene indicated by the structural formula (7), Bis(ethylenedioxo)tetrathiafluvalene indicated by the structural formula (8), and the like.

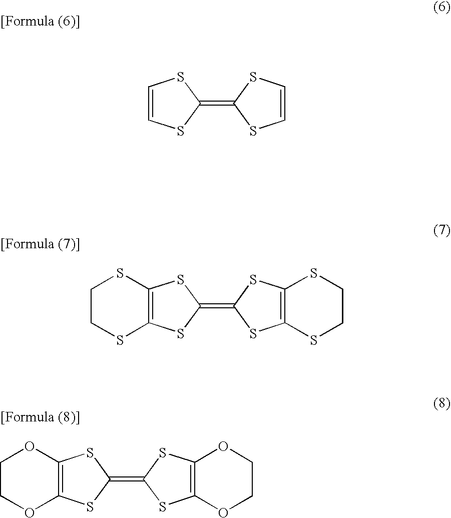

### Embodiment Mode 2

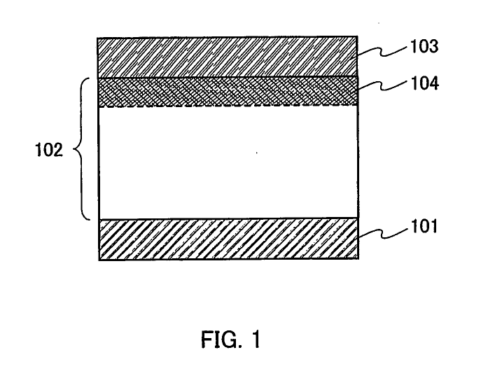

FIG. 1 schematically shows the element structure of a light emitting element according to the present invention. The light emitting element according to the present invention includes, between an anode 101 and a cathode 103, a layer 102 containing a luminescent material. A layer 104 containing an electron injecting composition according to the present invention is provided in contact with the cathode 103, as a portion of the layer 102 containing the luminescent material. Specifically, a layer that includes an electron injecting composition containing a benzoxazole derivative indicated by the general formula (1) and an electron donating organic compound is provided.

As the anode 101, known materials can be used; and for example, a metal, an alloy, a conductive compound, and a mixture thereof in which the work function is high (e.g., 4.0 eV or more) are preferably used. Specifically, gold (Au), platinum (Pt), nickel (Ni), tungsten (W), chromium (Cr), molybdenum (Mo), iron (Fe), cobalt (Co), copper (Cu), palladium (Pd), or nitride of a metal material (such as titanium nitride: TiN) and the like are given in addition to indium tin oxide (hereinafter referred to as ITO), indium tin oxide containing silicon, indium oxide containing zinc oxide (ZnO) at 2 to 20%, and the like.

On the other hand, as the cathode 103, known materials can be used; and for example, a metal, an alloy, a conductive compound, and a mixture thereof in which the work function is low (e.g., 3.8 eV or less) are preferably used. Specifically, a metal that belongs to Group 1 or 2 of the periodic table, namely, an alkali metal such as lithium (Li) and cesium (Cs); an alkaline earth metal such as magnesium (Mg), calcium (Ca) and strontium (Sr); an alloy containing the alkali metal or the alkaline earth metal (MgAg, AlLi); a rare earth metal such as europium (Eu) and ytterbium (Yb); and an alloy containing the rare earth metal can be given. It is to be noted that a material that has a higher work function, namely, a material that is normally used for an anode can be used to form the cathode since the electron injecting composition according to the present invention has a high electron injecting property. For example, the use of the electron injecting composition according to the present invention makes it possible to form the anode 103 composed of a metal or a conductive inorganic compound such as Al, Ag and ITO.

As the layer 102 containing the luminescent material, known materials can be used; and for example, both low molecular weight materials and polymer materials can be used. It is to be noted that the structure of materials for forming the layer 102 containing the luminescent material include not only a structure containing only organic compounds but also a structure containing also an inorganic compound as a part of thereof. In addition, the layer containing the luminescent material is formed by appropriately combining a hole injecting layer, a hole transporting layer, a hole blocking layer, a light emitting layer, an electron transporting layer, an electron injecting layer, and the like; and the layer containing the luminescent material may have a single layer structure or a laminated structure of plural layers. Specific materials are described in the following, which are used for a hole injecting layer, a hole transporting layer, a light emitting layer, an electron transporting layer, and an electron injecting layer.

As a hole injecting material that forms a hole injecting layer, a porphyrin compound is effective among organic compounds, and phthalocyanine (hereinafter, referred to as H₂-Pc), copper phthalocyanine (hereinafter, referred to as Cu-Pc), and the like can be used. In addition, a material that is obtained by chemical doping to a conductive polymer compound such as polyethylene dioxythiophene (hereinafter, referred to as PEDOT) doped with polystyrene sulfonate (hereinafter, referred to as PSS), and the like can be used. Moreover, a material containing a benzoxazole derivative and any one or a plurality of materials of TCQn, FeCl₃, C₆₀ and F₄TCNQ may be also used.

As a hole transporting material that forms a hole transporting layer, an aromatic amine compound (namely, a compound having a bond of benzene ring-nitrogen) is suitable. Materials that are used broadly include, for example, N,N′-bis(3-methylphenyl)-N,N′-diphenyl-[1,1′-biphenyl]-4,4′-diamine (hereinafter, referred to as TPD), 4,4′-bis[N-(1-naphthyl)-N-phenyl-amino]-biphenyl (hereinafter, referred to as α-NPD) which is a derivative thereof, starburst aromatic amine compounds such as 4,4′,4″-tris(N-carbazolyl)-triphenylamine (hereinafter, referred to as TCTA), 4,4′,4″-tris(N,N-diphenyl-amino)-triphenylamine (hereinafter, referred to as TDATA), and 4,4′,4″-tris[N-(3-methylphenyl)-N-phenyl-amino]-triphenylamine (hereinafter, referred to as MTDATA), and the like.

As a luminescent material that forms a light-emitting layer, specifically, metal complexes such as tris(8-quinolinolato)aluminum (hereinafter, referred to as Alq₃), tris(4-methyl-8-quinolinolato)aluminum (hereinafter, referred to as Almq₃), bis(10-hydroxybenzo[h]-quinolinato) beryllium (hereinafter, referred to as BeBq₂), bis(2-methyl-8-quinolinolato)-(4-hydroxy-biphenylil)-aluminum (hereinafter, referred to as BAlq), bis[2-(2-hydroxyphenyl)-benzoxazolate]zinc (hereinafter, referred to as Zn(BOX)₂), bis[2-(2-hydroxyphenyl)-benzothiazorato]zinc (hereinafter, referred to as Zn(BTZ)₂), and various fluorescent pigments are effective.

When a light-emitting layer is formed by combining a luminescent material with a guest material, quinacridone, diethyl quinacridone (hereinafter, referred to as DEQD), dimethyl quinacridone (hereinafter, referred to as DMQD), rubrene, perylene, coumarin, coumarin545T (hereinafter, referred to as C545T), DPT, Co-6, PMDFB, BTX, ABTX, DCM, DCJT, and triplet luminescent materials (phosphorescent materials) such as tris(2-phenylpyridine)iridium (hereinafter, referred to as Ir(ppy)₃), 2,3,7,8,12,13,17,18-octaethyl-21H,23H-porphyrin-platinum (hereinafter, referred to as PtOEP) can be used as the guest material.

As an electron transporting material that forms an electron transporting layer, a metal complex having a quinoline skeleton or a benzoquinoline skeleton such as Alq₃, Almq₃ and BeBq₂ as described above, BAlq that is a mixed ligand complex or the like is suitable. In addition, a metal complex having an oxazole ligand such as Zn(BOX)₂, and a metal complex having a thiazole ligand such as Zn(BTZ)₂ can be also used. Moreover, in addition to the metal complex, oxadiazole derivatives such as 2-(4-biphenylil)-5-(4-tert-butylphenyl)-1,3,4-oxadiazole (hereinafter, referred to as PBD), and 1,3-bis[5-(p-tert-butylphenyl)-1,3,4-oxadiazol-2-yl]benzene (hereinafter, referred to as OXD-7), or triazole derivatives such as 3-(4-tert-butylphenyl)-4-phenyl-5-(4-biphenylil)-1,2,4-triazole (hereinafter, referred to as TAZ), and 3-(4-tert-butylphenyl)-4-(4-ethylphenyl)-5-(4-biphenylil)-1,2,4-triazole (hereinafter, referred to as p-EtTAZ) can be also used.

As an electron injecting material that forms an electron injecting layer, it is preferable to use an electron injecting composition according to the present invention. Specifically, as shown in Embodiment Mode 1, the electron injecting composition containing a benzoxazole derivative and an electron donating organic compound is preferably used.

The electron injecting composition according to the present invention is excellent in light-transmitting property. Therefore, light that is emitted from the luminescent material can be emitted outside efficiently. In other words, the light extraction efficiency can be improved.

In addition, the electron injecting composition according to the present invention is excellent in electron injecting property. Therefore, drive voltage is prevented from increasing even when a material that has a higher work function is used for the cathode.

Further, only organic compounds are used to form the electron injecting composition according to the present invention, and a highly dangerous alkali metal and the like are not used. Therefore, the risk of accidents such as a fire due to the use of an alkali metal can be reduced, and a light-emitting element and a light-emitting device can be manufactured more safely.

Moreover, the electron injecting composition according to the present invention is not easily crystallized. Therefore, when the electron injecting composition according to the present invention is used to form a light emitting element, a light emitting element that has a longer lifetime can be formed.

### Embodiment 1

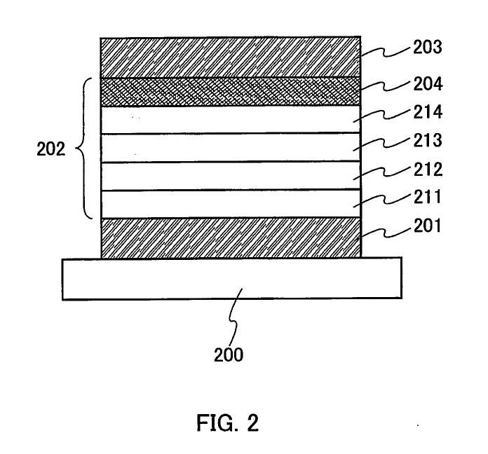

In the present embodiment, a structure is described, in which light that is generated in a layer containing a luminescent material is emitted from both an anode and a cathode of a light-emitting element (hereinafter referred to as a dual emission structure). A light-emitting element according to the present invention will be described with reference to FIG. 2, in which the electron injecting composition according to the present invention is provided in a part of the layer containing the luminescent material.

First, a first electrode of the light emitting element is formed over a substrate 200. In the present embodiment, the first electrode serves as an anode. With the use of an ITO that is a transparent conductive film as a material, an anode 201 is formed by sputtering to be 110 nm in film thickness.

Next, a layer 202 containing a luminescent material is formed on the anode 201. It is to be noted that the layer 202 containing the luminescent material in the present embodiment has a laminated structure of a hole injecting layer 211, a hole transporting layer 212, a light-emitting layer 213, an electron transporting layer 214, and an electron injecting layer 204.

The substrate with the anode 201 formed thereover is fixed in a substrate holder of a commercially available vacuum evaporation system while the surface with the first electrode 201 is kept downside. Then, Cu-Pc is put in an evaporation source provided inside the vacuum evaporation system and the hole injecting layer 211 is formed by evaporation using a resistance heating method to be 20 nm in film thickness. It is to be noted that known hole injecting materials can be used for a material that forms the hole injecting layer 211.

The hole transporting layer 212 is then formed by using a highly hole transporting material. Known hole transporting materials can be used for a material that forms the hole transporting layer 212. In the present embodiment, for the hole transporting layer 212, α-NPD is evaporated in the same way to be 40 nm in film thickness.

Then, the light-emitting layer 213 is formed. It is to be noted that luminescence is generated by recombination of a hole and an electron in the light-emitting layer 213. In the present embodiment, with the use of Alq₃ to serve as a host material and DMQD to serve as a guest material among materials that forms the light-emitting layer 213, the light-emitting layer 213 with a film thickness of 40 nm is formed by co-evaporation so that DMQD is contained at 1 weight %.

The electron transporting layer 214 is then formed. Known electron transporting materials can be used for a material that forms the electron transporting layer 214. In the present embodiment, Alq₃ is used to form the electron transporting layer 214 with a film thickness of 20 nm by evaporation.

Then, the electron injecting layer 204 is formed. An electron injecting composition according to the present invention is used to form the electron injecting layer 204. The electron injecting composition includes a benzoxazole derivative indicated by the general formula (1) and a tetrathiafulvalene derivative indicated by the general formula (5). In the present embodiment, the electron injecting layer 204 with a film thickness of 10 nm is formed by co-evaporation so that the molar ratio of a benzoxazole derivative indicated by the following structural formula (2) and a tetrathiafulvalene derivative indicated by the following structural formula (6) is 1:1.

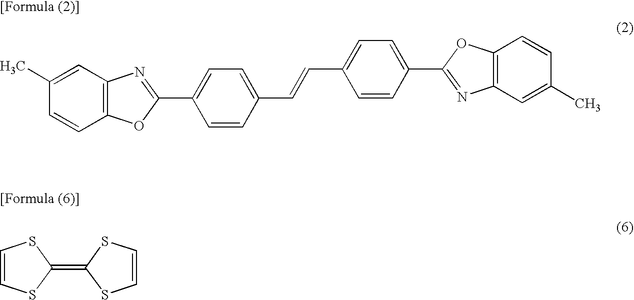

Thus, after the layer 202 containing the luminescent material is formed by laminating the hole injecting layer 211, the hole transporting layer 212, the light-emitting layer 213, the electron transporting layer 214 and the electron injecting layer 204, a second electrode is formed by sputtering or evaporation. In the present embodiment, the second electrode serves as a cathode.

It is to be noted that a cathode 203 is formed so as to be in contact with the electron injecting layer 204 that is excellent in electron injecting property. Therefore, in the present embodiment, an ITO (110 nm) is formed on the layer containing the luminescent material 202 by sputtering to obtain the cathode 203.

In this way as described above, a dual emission type light-emitting element is formed.

The electron injecting composition according to the present invention is excellent in light-transmitting property. Therefore, light that is emitted from a luminescent material can be emitted outside efficiently. In other words, the light extraction efficiency from the cathode side can be improved.

In addition, as shown in the present embodiment, light that is emitted from the cathode side and light that is emitted from the anode side can be made almost equal to each other in the dual emission structure by forming the electron injecting layer with the use of a highly light transmitting electron injecting composition. That is to say, it becomes possible to see images of almost the same quality from both the cathode side and the anode side.

Further, only organic compounds are used to form the electron injecting composition according to the present invention, and a highly dangerous alkali metal and the like are not used. Therefore, a light emitting element can be manufactured more safely.

Moreover, the electron injecting composition according to the present invention is not easily crystallized. Therefore, when the electron injecting composition according to the present invention is used to form a light emitting element, a light emitting element that has a longer lifetime can be formed.

In the present embodiment, the anode is provided on the substrate side; however, the cathode may be provided on the substrate side and the layer containing the luminescent material may be stacked thereon in the inverted order from the order shown in the present embodiment. That is to say, on the cathode that is formed on the substrate side, the electron injecting layer using the electron injecting composition according to the present invention, the electron transporting layer, the light emitting layer, the hole transporting layer, the hole injecting layer, and the anode may be laminated.

### Embodiment 2

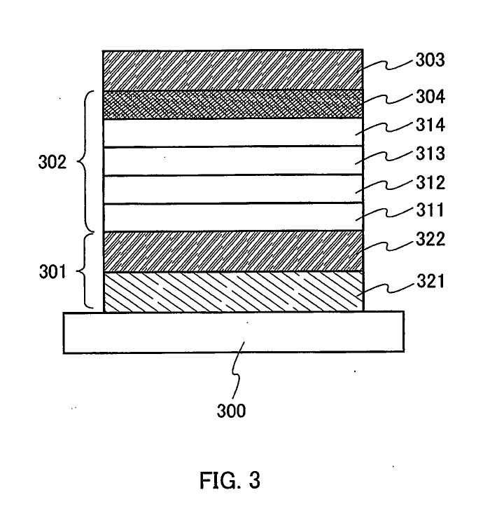

In the present embodiment, a structure will be described with reference to FIG. 3, in which light that is generated in a layer containing a luminescent material is emitted from one side of a light emitting element and light is emitted from the side opposite to a substrate (hereinafter referred to as a top emission structure).

It is to be noted that only a different portion from the structure in Embodiment 1 is described here. In the present embodiment, the structure other than the first electrode is the same as in Embodiment 1; and thus, an explanation thereof is omitted.

The first electrode in the present embodiment serves as an anode, from which light that is generated in a layer 302 containing a luminescent material is not emitted outside. That is to say, as a material to form the anode, nitride or carbide of an element that belongs to Group 4, 5, or 6 of the periodic table, which has a higher work function and a light-shielding effect, can be used. Specifically, titanium nitride, zirconium nitride, titanium carbide, zirconium carbide, tantalum nitride, tantalum carbide, molybdenum nitride, molybdenum carbide, and the like can be used. In addition, the anode can be also formed by laminating a transparent conductive film that has a higher work function and a conductive film (a reflective conductive film) that has reflexivity (including a case of having a light-shielding effect).

In the present embodiment, a case in which a reflective conductive film and a transparent conductive film that has a higher work function are laminated to form an anode 301 will be described.

Specifically, a reflective conductive film 321 is formed by forming an aluminum-silicon (Al—Si) film of 300 nm thick over a substrate 300 and then laminating a titanium (Ti) film of 100 nm thick. Then, an ITO of 20 nm is formed thereon as a transparent conductive film 322.

After the anode 301 is formed, similarly to Embodiment 1, a hole injecting layer 311, a hole transporting layer 312, a light emitting layer 313, an electron transporting layer 314, an electron injecting layer 304 and a cathode 303 are stacked successively.

As described above, a top emission type light emitting element can be formed, in which light is emitted only from the cathode side. The electron injecting composition according to the present invention is excellent in light-transmitting property. Therefore, light that is emitted from a luminescent material can be emitted outside efficiently. In other words, the light extraction efficiency from the cathode side can be improved.

In the present embodiment, a case in which a reflective conductive film and a transparent conductive film that has a higher work function are laminated to form the anode is described; however, it is not always necessary to employ the laminated structure and the anode can have a single layer structure as long as a material that has a higher work function and a light-shielding effect is used.

Further, in the present embodiment, a structure, in which the anode is formed on the substrate side, is described. However, the present invention is not limited to this structure. After providing the cathode on the substrate side, the layer containing the luminescent material may be stacked thereon in the inverted order from the order shown in the present embodiment. That is to say, it is possible to form the cathode on the substrate side, and form the layer containing the electron injecting composition according to the present invention so as to be in contact with the cathode so that light from the layer containing the luminescent material is emitted from the substrate side (bottom emission structure).

### Embodiment 3

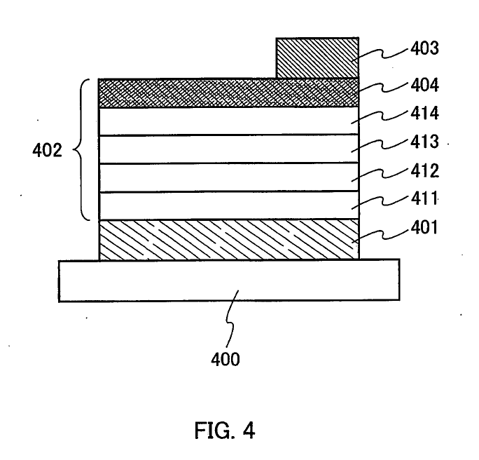

In the present embodiment, a structure (top emission structure) will be described, in which light that is generated in a layer containing a luminescent material is emitted from one side of a light emitting element as in Embodiment 2, and specifically, light is emitted from the side of an electron injecting layer 404 that is included in the layer 402 containing the luminescent material as shown in FIG. 4.

First, a first electrode 401 is formed over a substrate 400. The first electrode in the present embodiment serves as an anode, from which light that is generated in the layer 402 containing the luminescent material is not emitted. For the anode, nitride or carbide of an element that belongs to Group 4, 5, or 6 of the periodic table, which has a higher work function and a light-shielding effect, can be used. Specifically, titanium nitride, zirconium nitride, titanium carbide, zirconium carbide, tantalum nitride, tantalum carbide, molybdenum nitride, molybdenum carbide, and the like can be used. In the present embodiment, as the first electrode 401, a titanium nitride film of 100 nm thick is formed.

Next, as in Embodiments 1 and 2, a hole injecting layer 411, a hole transporting layer 412, a light emitting layer 413, an electron transporting layer 414, and an electron injecting layer 404 are laminated successively to form the layer 402 containing the luminescent material.

Then, a second electrode 403 is formed on a portion of the layer 402 containing the luminescent material. In the present embodiment, since the second electrode (cathode) 403 that serves as an auxiliary electrode is formed on the portion of the layer 402 containing the luminescent material, light that is generated in the layer containing the luminescent material is emitted from a portion on which the second electrode (cathode) 403 is not formed. In the present embodiment, it is not always necessary to use a light transmitting material as a material for the second electrode 403 as long as it is a cathode material that has a lower work function, and a light shielding material may be also used.

It is to be noted that the structures described in Embodiments 1 to 3 can be appropriately combined and implemented.

### Embodiment 4

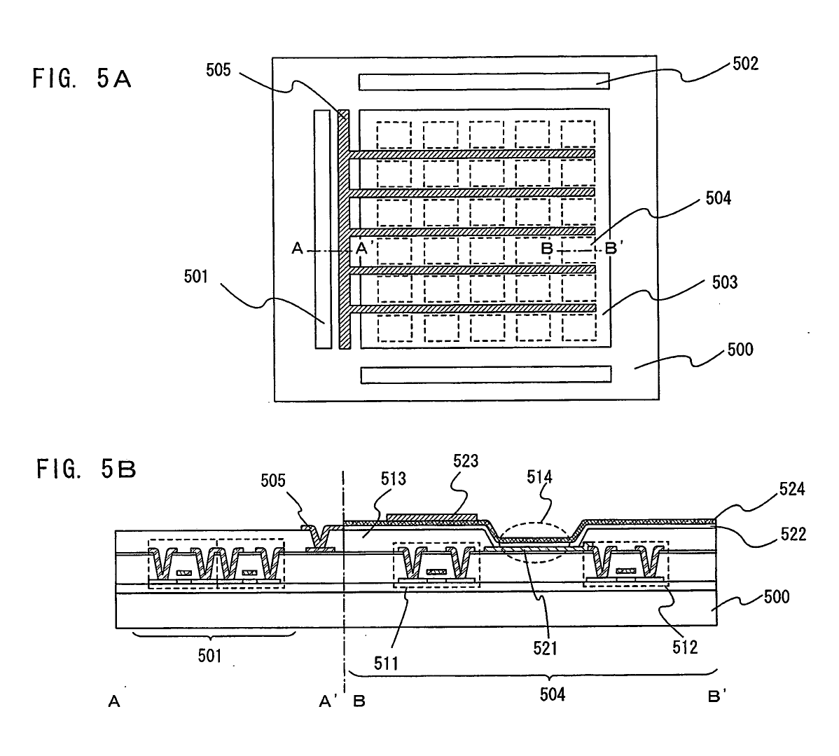

In the present embodiment, a structure will be described more in detail with reference to FIGS. 5A and 5B, in which the second electrode shown in Embodiment 3 is used as an auxiliary electrode.

FIG. 5A is a top view of a light emitting device, and FIG. 5B is a partial cross-sectional view of FIG. 5A along with A-A′ and B-B′. Over a substrate 500, a driving circuit portion (source side driving circuit) 501, a driving circuit portion (gate side driving portion) 502, a pixel portion 503 including a plurality of pixels 504, and an auxiliary wiring 505 are formed.

Next, a cross-sectional structure will be described with reference to FIG. 5B. Although a plurality of pixels are formed over the substrate, a cross section of one of the pixels 504 and a cross section of a driving circuit portion (source side driving circuit) 501 are shown in FIG. 5B.

The driving circuit portion 501 may be formed by using a known CMOS circuit, PMOS circuit, or NMOS circuit. Although the present embodiment describes a driver integrated type in which the driving circuit is formed over the substrate, which is not always necessary, the driving circuit can be also provided outside the substrate, not over the substrate.

In addition, the pixel 504 includes a switching TFT 511, a current control TFT 512, and a first electrode 521 that is electrically connected to a drain of the current control TFT 512. It is to be noted that an insulator 513 is formed to cover an edge portion of the first electrode 521.

A layer containing a luminescent material is formed on the first electrode 521. Specifically, as described in Embodiment 3, a layer 522 containing a luminescent material except for an electron injecting layer is (a hole injecting layer, a hole transporting layer, a light emitting layer, an electron transporting layer and the like) formed on the first electrode that serves as an anode, and an electron injecting layer 524 containing the electron injecting composition according to the present invention is formed thereon as a top layer.

Further, a second electrode (auxiliary electrode) 523 that serves as a cathode is formed on a portion of the electron injecting layer 524. It is preferable that the second electrode (auxiliary electrode) 523 be provided on an area including no light-emitting area 514 where the first electrode 521 and the layer 522 containing the luminescent material are stacked. FIG. 5B shows an example in which the second electrode (auxiliary electrode) 523 is provided over the insulator 513. By forming the second electrode (auxiliary electrode) over the insulator 513, luminescence from the light-emitting area 514 is prevented from being blocked. Therefore, decrease of the aperture ratio can be prevented. It is to be noted that a light-transmitting material is preferably used when the second electrode (auxiliary electrode) is formed on the light-emitting area 514.

The second electrode (auxiliary electrode) 523 in each pixel is electrically connected by the auxiliary wiring 505, and all the auxiliary wirings are connected to one wiring on the driving circuit portion (source side driving circuit) 501 side. Therefore, the second electrode (auxiliary electrode) that serves as a cathode is kept at a constant voltage in all pixels.

### Embodiment 5

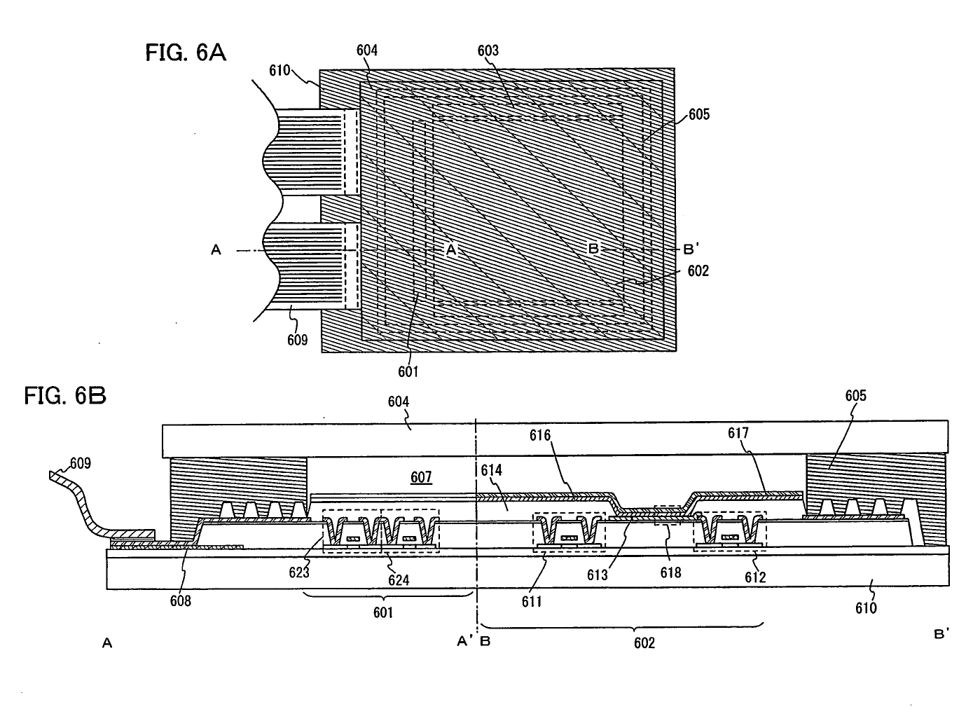

In the present embodiment, a light emitting device including a light emitting element according to the present invention in a pixel portion will be described with reference to FIGS. 6A and 6B. FIG. 6A is a top view of a light emitting device, and FIG. 6B is a partial cross-sectional view of FIG. 6A along with A-A′ and B-B′. Reference numeral 601 indicated by a dotted line denotes a driving circuit portion (source side driving circuit), 602 denotes a pixel portion, and 603 denotes a driving circuit portion (gate side driving circuit). Reference numeral 604 denotes a sealing substrate, 605 denotes a sealing material, and the inside surrounded by the sealing material 605 is a space 607.

A lead wiring 608 transmits signals that are inputted to the source side driving circuit 601 and the gate side driving circuit 603, and receives a video signal, a clock signal, a start signal, a reset signal and the like from an FPC (flexible printed circuit) 609 that serves as an external input terminal. Only the FPC is shown herein; however, a printed wiring board (PWB) may be connected to the FPC. The light-emitting device in the specification includes not only a light-emitting device body itself but also a light-emitting device to which an FPC or a PWB is attached.

Next, the cross-sectional structure will be described with reference to FIG. 6B. The driving circuit portion and the pixel portion are formed over an element substrate 610, and the source side driving circuit 601 that is a driving circuit portion and one pixel in the pixel portion 602 are shown here.

The source side driving circuit 601 is formed by a CMOS circuit in which an n-channel type TFT 623 and a p-channel type TFT 624 are combined. TFTs forming the driving circuit may be formed by a known CMOS circuit, PMOS circuit or NMOS circuit. Although the present embodiment shows a driver integrated type in which a driving circuit is formed over a substrate, which is not always necessary, a driving circuit can be also provided outside a substrate, not over a substrate.

The pixel portion 602 is formed by a plurality of pixels each including a switching TFT 611, a current control TFT 612 and a first electrode 613 that is electrically connected to a drain of the current control TFT 612. It is to be noted that an insulator 614 is formed to cover an edge portion of the first electrode 613. The insulator 614 is formed by using a positive photosensitive acrylic resin film here.

In order to improve coverage, an upper edge portion or a lower edge portion of the insulator 614 is formed to have a curved surface formed with a curvature. For example, when a positive photosensitive acryl is used as a material for the insulator 614, it is preferable that only an upper edge portion of the insulating material 614 has a curved surface with a curvature radius (0.2 μm to 3 μm). As the insulator 614, any of a negative photosensitive material that becomes insoluble in an etchant by light and a positive photosensitive material that becomes soluble in an etchant by light can be used.

Over the first electrode 613, a layer 616 containing a luminescent material and a second electrode 617 are formed, respectively. Here, as a material to be used for the first electrode 613 that serves as an anode, a material that has a higher work function is preferably used. Specifically, a single layer film such as an ITO film, an indium tin oxide film containing silicon, an indium oxide film containing zinc oxide at 2 to 20%, a titanium nitride film, a chromium film, a tungsten film, a Zn film, a Pt film and the like can be used. In addition, a lamination layer of a titanium nitride film and a film mainly containing aluminum, a three layer-structure of a titanium nitride film, a film mainly containing aluminum and a titanium nitride film, and the like can be also used. When the first electrode 613 has a laminated structure, resistance as a wiring can be low, ohmic contact can be favorable; moreover, the first electrode 613 can serve as an anode.

The layer 616 containing the luminescent material is formed by evaporation using an evaporation mask or ink-jet method. The layer 616 containing the luminescent material includes an electron injecting composition according to the present invention. As a material that is used in combination with the electron injecting composition according to the present invention, a low molecular weight material, a middle molecular weight material (including oligomer and dendrimer), or a polymer material may be used. As a material to be used for a layer containing a luminescent material, an organic compound is normally used as a single layer or a lamination layer. However, the present invention also includes a structure in which an inorganic compound is used as a part of a film composed of an organic material.

Further, as a material to be used for the second electrode (cathode) 617 that is formed on the layer 616 containing the luminescent material, a material that has a lower work function (Al, Ag, Li, Ca, or an alloy thereof such as MgAg, MgIn, AlLi, CaF₂ or CaN) is preferably used. However, since the electron injecting composition according to the present invention has a high electron injecting property, the second electrode (cathode) may be formed by using a material that has a higher work function, which is normally used for an anode. When light that is generated in the layer 616 containing the luminescent material is transmitted through the second electrode 617, a lamination layer of a metal thin film with a thinner film thickness and a transparent conductive film (ITO, indium oxide containing zinc oxide at 2 to 20%, zinc oxide (ZnO) and the like) may be preferably used for the second electrode (cathode) 617.

In FIG. 6B, the second electrode is formed on the whole surface of the layer containing the luminescent material. However, as shown in FIG. 5, the second electrode may be formed on a portion of the layer containing the luminescent material to be used as an auxiliary electrode.

Furthermore, the sealing substrate 604 is attached to the element substrate 610 with the sealing material 605 to provide a structure in which the light-emitting element 618 is provided in the space 607 surrounded by the element substrate 610, the sealing substrate 604 and the sealing material 605. It is to be noted that the space 607 is filled with an inert gas (such as nitrogen or argon) or the sealing material 605.

It is preferable to use an epoxy based resin for the sealing material 605, and it is desired that these materials prevent permeation of water or oxygen as far as possible. In addition, as a material for the sealing substrate 604, a plastic substrate including FRP (Fiberglass-Reinforced Plastics), PVF (polyvinyl fluoride), mylar, polyester, acryl or the like can be used in addition to a glass substrate and a quartz substrate.

As described above, the light emitting device including the light emitting element according to the present invention can be obtained.

The highly light-transmitting electron injecting composition is used for the light emitting device according to the present invention. Therefore, light that is emitted from the luminescent material can be emitted outside efficiently. In other words, the light extraction efficiency can be improved. In particular, when both of the first electrode and the second electrode are formed by using a light-transmitting material, an image of the same quality can be seen from the both side.

Furthermore, since the electron injecting composition, which is excellent in electron injecting property, is used, drive voltage is prevented from increasing even when a material that has a higher work function is used for the cathode. Therefore, the power consumption of the light emitting device can be reduced.

Further, the electron injecting composition, which contains no highly dangerous material, is used for the light emitting device according to the present invention. Therefore, a light emitting device can be manufactured more safely.

Moreover, the electron injecting composition, which is not easily crystallized, is used. Therefore, crystallization in the light emitting element can be suppressed and stable luminescence can be obtained for a long stretch of time.

It is to be noted that the light emitting device shown in the present embodiment can be implemented by freely combining the structures shown in Embodiments 1 to 4.

### Embodiment 6

In the present embodiment, various electronic devices including, as a part thereof, a light-emitting device manufactured by using a light-emitting element according to the present invention will be described.

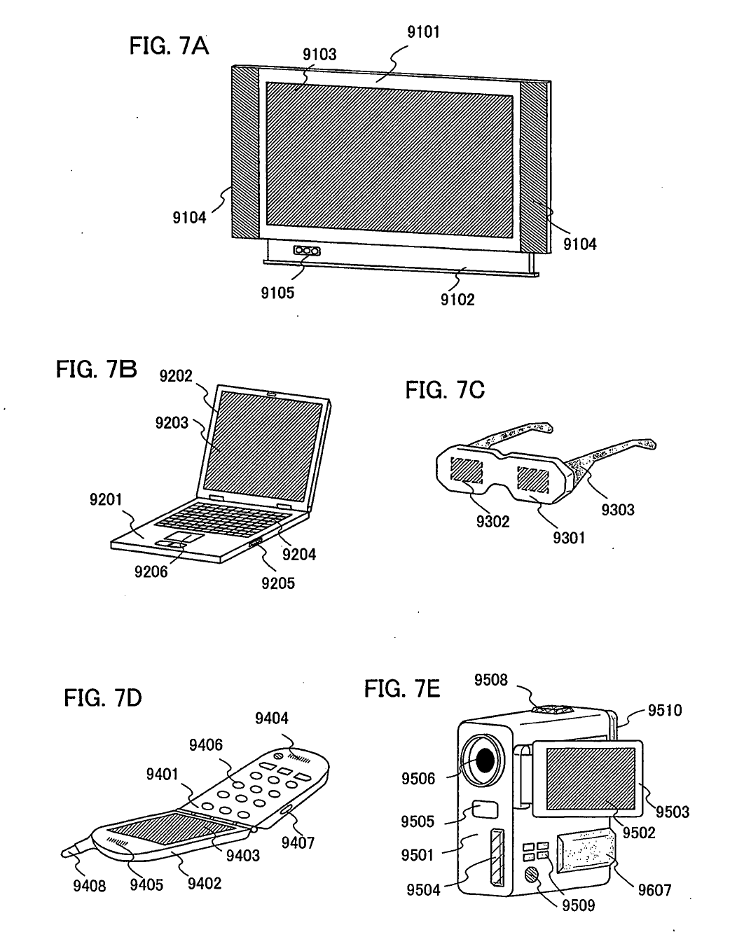

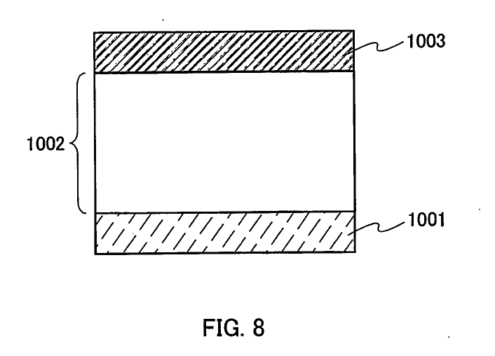

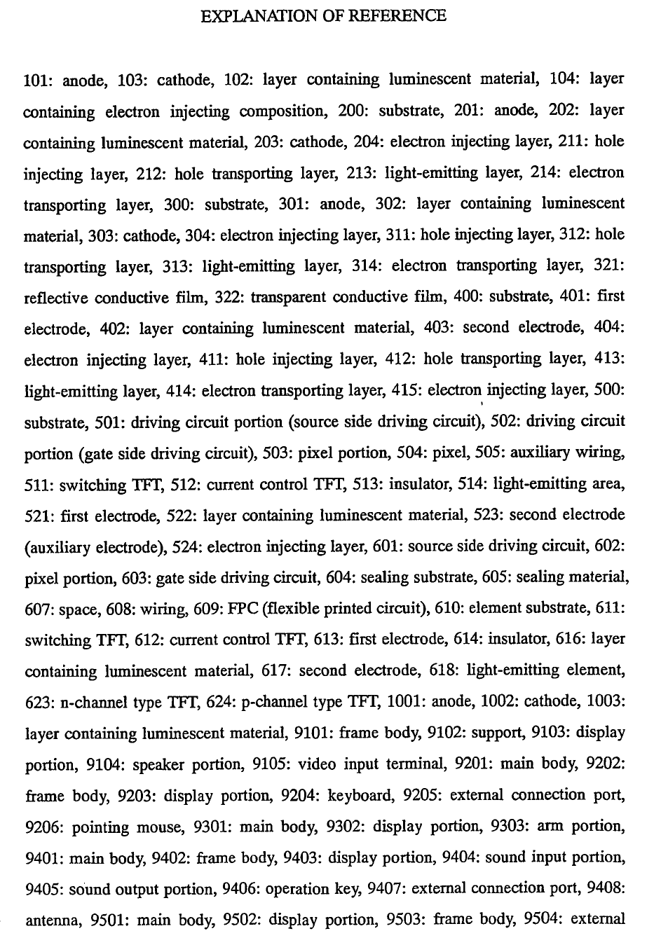

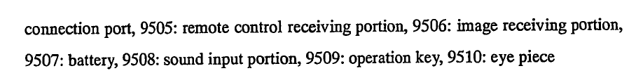

Electronic devices manufactured by using a light-emitting device including a light-emitting element according to the present invention include a video camera, a digital camera, a goggle-type display, a navigation system, a sound reproduction device (such as an in-car audio system or an audio set), a computer, a game machine, a personal digital assistant (such as a mobile computer, a cellular phone, a portable game machine, or an electronic book), an image reproduction device equipped with a recording medium (specifically, a device equipped with a display device that is able to reproduce a recording medium such as a digital versatile disc (DVD) and display the image) and the like. FIGS. 7A to 7E show specific examples of these electronic devices.

FIG. 7A is a TV set, which includes a frame body 9101, a support 9102, a display portion 9103, speaker portions 9104, a video input terminal 9105 and the like. The TV set is manufactured by using a light-emitting device including a light emitting element according to the present invention for the display portion 9103. It is to be noted that the TV set includes all types of devices for displaying information such as for a computer, for receiving TV broadcasting and for displaying advertisement.

FIG. 7B is a computer, which includes a main body 9201, a frame body 9202, a display portion 9203, a keyboard 9204, an external connection port 9205, a pointing mouse 9206 and the like. The personal computer is manufactured by using a light-emitting device including a light emitting element according to the present invention for the display portion 9203.

FIG. 7C is a goggle-type display, which includes a main body 9301, a display portion 9302 and an arm portion 9303. The goggle-type display is manufactured by using a light-emitting device including a light emitting element according to the present invention for the display portion 9302.

FIG. 7D is a cellular phone, which includes a main body 9401, a frame body 9402, a display portion 9403, a sound input portion 9404, a sound output portion 9405, an operation key 9406, an external connection port 9407, an antenna 9408 and the like. The cellular phone is manufactured by using a light-emitting device including a light emitting element according to the present invention for the display portion 9403. It is to be noted that power consumption of the cellular phone can be reduced by displaying white characters on a black background in the display portion 9403.

FIG. 7E is a video camera, which includes a main body 9501, a display portion 9502, a frame body 9503, an external connection port 9504, a remote control receiving portion 9505, an image receiving portion 9506, a battery 9507, a sound input portion 9508, operation keys 9509, an eye piece 9510 and the like. The video camera is manufactured by using a light-emitting device including a light emitting element according to the present invention for the display portion 9502.

As described above, a light emitting device including a light emitting element according to the present invention can be applied quite broadly, and this light emitting device can be applied to electronic devices of various fields. By using the light emitting device including the light emitting element according to the present invention, an electronic device that needs lower power consumption can be provided, and an electronic device that has a longer lifetime can be provided.

1. An electron injecting composition comprising:
a benzoxazole derivative indicated by a general formula (1), and
an electron donating organic compound, 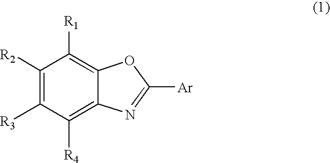
wherein Ar represents an aryl group, each of R1 to R4 represents hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group.

2. An electron injecting composition comprising:
a benzoxazole derivative indicated by a structural formula (2), and
an electron donating organic compound.

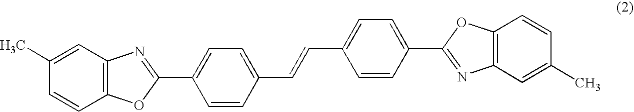

3. An electron injecting composition comprising:
a benzoxazole derivative indicated by a structural formula (3), and
an electron donating organic compound.

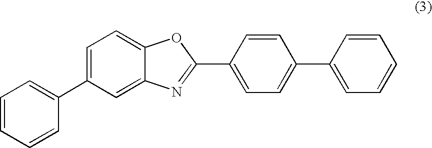

4. An electron injecting composition comprising:
a benzoxazole derivative indicated by a structural formula (4), and
an electron donating organic compound.

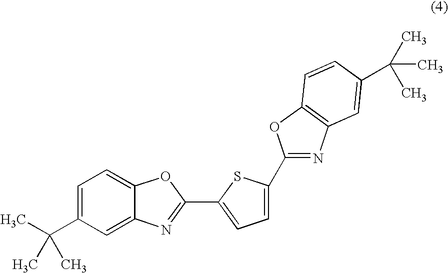

5. An electron injecting composition according to any one of claims 1 to 4, wherein the electron donating organic compound is a tetrathiafulvalene derivative indicated by a general formula (5), 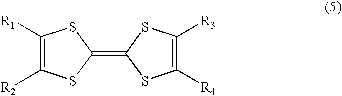
wherein each of R1 to R4 represents hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group.

6. An electron injecting composition according to any one of claims 1 to 4, wherein the electron donating organic compound is a tetrathiafulvalene derivative indicated by a structural formula (6).

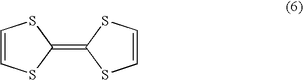

7. An electron injecting composition according to any one of claims 1 to 4, wherein the electron donating organic compound is a tetrathiafulvalene derivative indicated by a structural formula (7).

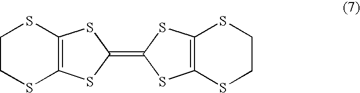

8. An electron injecting composition according to any one of claims 1 to 4, wherein the electron donating organic compound is a tetrathiafulvalene derivative indicated by a structural formula (8).

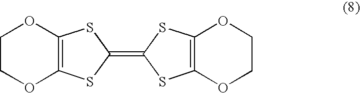

9. A light emitting element comprising:
an anode,
a cathode, and
a layer containing a luminescent material between the anode and the cathode, wherein a layer containing a benzoxazole derivative indicated by a general formula (1) and an electron donating organic compound is in contact with the cathode as a portion of the layer containing the luminescent material, and 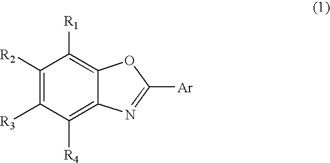
wherein Ar represents an aryl group, each of R1 to R4 represents hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group.

10. A light emitting element comprising:
an anode,
a cathode, and
a layer containing a luminescent material between the anode and the cathode, wherein a layer containing a benzoxazole derivative indicated by a structural formula (2) and an electron donating organic compound is in contact with the cathode as a portion of the layer containing the luminescent material.

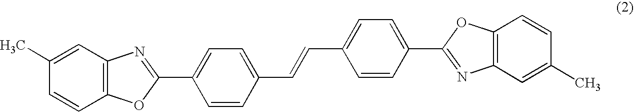

11. A light emitting element comprising:
an anode,
a cathode, and
a layer containing a luminescent material between the anode and the cathode, wherein a layer containing a benzoxazole derivative indicated by a structural formula (3) and an electron donating organic compound is in contact with the cathode as a portion of the layer containing the luminescent material.

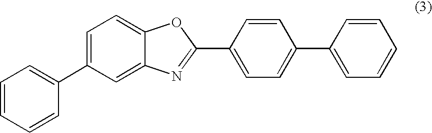

12. A light emitting element comprising:
an anode,
a cathode, and
a layer containing a luminescent material between the anode and the cathode, wherein a layer containing a benzoxazole derivative indicated by a structural formula (4) and an electron donating organic compound is in contact with the cathode as a portion of the layer containing a luminescent material.

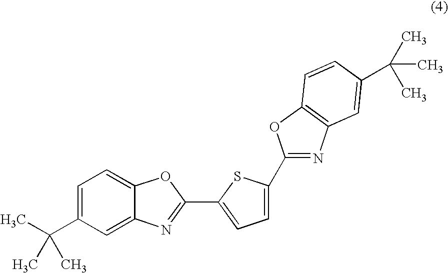

13. A light emitting element according to any one of claims 9 to 12,
wherein the electron donating organic compound is a tetrathiafulvalene derivative indicated by a general formula (5), 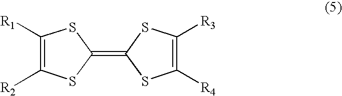
wherein each of R1 to R4 represents hydrogen, halogen, a cyano group, an alkyl group having 1 to 10 carbon atoms, a haloalkyl group having 1 to 10 carbon atoms, an alkoxyl group having 1 to 10 carbon atoms, a substituted or unsubstituted aryl group, or a substituted or unsubstituted heterocyclic group.

14. A light emitting element according to any one of claims 9 to 12,
wherein the electron donating organic compound is a tetrathiafulvalene derivative indicated by a structural formula (6).

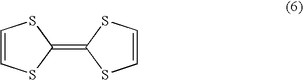

15. A light emitting element according to any one of claims 9 to 12,
wherein the electron donating organic compound is a tetrathiafulvalene derivative indicated by a structural formula (7).

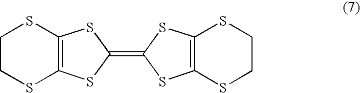

16. A light emitting element according to any one of claims 9 to 12,
wherein the electron donating organic compound is a tetrathiafulvalene derivative indicated by a structural formula (8).

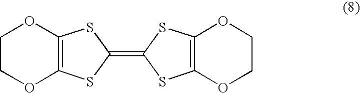

17. A light emitting element according to any one of claims 1 to 4, wherein a molar ratio of the benzoxazole derivative to the electron donating organic compound is from 0.5 to 10,

18. A light emitting element according to any one of claims 9 to 12, wherein a molar ratio of the benzoxazole derivative to the electron donating organic compound is from 0.5 to 10,

19. A light emitting device including the light emitting element according to any one of claims 9 to 12.
